(19) United States
(12) Patent Application Publication
(10) Pub. No.: US 2016/0190393 A1
(43) Pub. Date: Jun. 30, 2016

(54) SEMICONDUCTOR LIGHT EMITTING ELEMENT AND METHOD FOR MANUFACTURING THE SAME

(71) Applicant: Kabushiki Kaisha Toshiba, Minato-ku (JP)

(72) Inventors: Toshihide ITO, Minato (JP); Shinya NUNOUE, Ichikawa (JP)

(73) Assignee: Kabushiki Kaisha Toshiba, Minato-ku (JP)

(21) Appl. No.: 14/976,848

(22) Filed: Dec. 21, 2015

(30) Foreign Application Priority Data
Dec. 26, 2014 (JP) 2014-265052

(51) Int. Cl. H01L 33/40; H01L 33/00

(52) U.S. Cl. CPC H01L 33/405; H01L 33/0008; H01L 33/0095; H01L 2933/0016

(57) ABSTRACT

According to one embodiment, a semiconductor light emitting element includes a first semiconductor layer of a first conductivity type, a second semiconductor layer of a second conductivity type including first and second semiconductor regions, a third semiconductor layer provided between the first and second semiconductor layers, a first electrode layer electrically connected to the first semiconductor layer, and a second electrode layer electrically connected to the second semiconductor layer. The second and third semiconductor layers are disposed between the second electrode layer and the first semiconductor layer. The second electrode layer includes a first metal region contacting the first semiconductor region and including silver, a second metal region contacting the second semiconductor region and including silver, and a third metal region contacting the first metal region and including silver. The first metal region is disposed between the third metal region and the first semiconductor region.

### CROSS-REFERENCE TO RELATED APPLICATIONS

This application is based upon and claims the benefit of priority from Japanese Patent Application No. 2014-265052, filed on Dec. 26, 2014; the entire contents of which are incorporated herein by reference.

### FIELD

Embodiments described herein relate generally to a semiconductor light emitting device and a method for manufacturing the same.

### BACKGROUND

Semiconductor light emitting elements such as LEDs (Light Emitting Diodes), etc., have configurations in which silver (Ag) that has a high reflectance is used as electrodes to increase the light extraction efficiency. On the other hand, there is a tendency for the light emission to be strong at the vicinity of the n-side electrode; and the uniformity of the light emission is low. Therefore, heat may concentrate at the portions where the light emission is strong; and the luminous efficiency may decrease. The reliability also degrades. Fluorescers that are used with the LED also may degrade due to the heat. It is desirable to increase the uniformity of the light emission.

### BRIEF DESCRIPTION OF THE DRAWINGS

FIG. 1A to FIG. 1D are schematic cross-sectional views showing a semiconductor light emitting element according to a first embodiment;

FIG. 2A to FIG. 2E are schematic views showing a characteristic of the semiconductor light emitting element;

FIG. 3A to FIG. 3E are graphs of the characteristic of the semiconductor light emitting element;

FIG. 4 is a graph of a characteristic of the semiconductor light emitting element;

FIG. 5 is a graph of a characteristic of the semiconductor light emitting element;

FIG. 6A to FIG. 6C are graphs of characteristics of the semiconductor light emitting element;

FIG. 7 is a schematic cross-sectional view showing the semiconductor light emitting element according to the first embodiment;

FIG. 8A to FIG. 8C are schematic cross-sectional views showing portions of semiconductor light emitting elements according to the first embodiment;

FIG. 9 is a schematic cross-sectional view showing one other semiconductor light emitting element according to the first embodiment;

FIG. 10 is a schematic cross-sectional view showing one other semiconductor light emitting element according to the first embodiment;

FIG. 11 is a schematic plan view showing the one other semiconductor light emitting element according to the first embodiment;

FIG. 12A and FIG. 12B are schematic cross-sectional views showing a semiconductor light emitting element according to a second embodiment; and

FIG. 13 is a flowchart showing a method for manufacturing a semiconductor light emitting element according to a third embodiment.

### DETAILED DESCRIPTION

According to one embodiment, a semiconductor light emitting element includes a first semiconductor layer of a first conductivity type, a second semiconductor layer of a second conductivity type including a first semiconductor region and a second semiconductor region, a third semiconductor layer provided between the first semiconductor layer and the second semiconductor layer, a first electrode layer electrically connected to the first semiconductor layer, and a second electrode layer electrically connected to the second semiconductor layer. The second semiconductor layer and the third semiconductor layer are disposed between the second electrode layer and the first semiconductor layer. The second electrode layer includes a first metal region contacting the first semiconductor region and including silver, a second metal region contacting the second semiconductor region and including silver, and a third metal region contacting the first metal region and including silver. The first metal region is disposed between the third metal region and the first semiconductor region. A distance between the first metal region and the first electrode layer is shorter than a distance between the second metal region and the first electrode layer. The first metal region has a first average grain size, the second metal region has a second average grain size smaller than the first average grain size, and the third metal region has a third average grain size smaller than the first average grain size.

According to another embodiment, a semiconductor light emitting element includes a first semiconductor layer of a first conductivity type, a second semiconductor layer of a second conductivity type including a first semiconductor region and a second semiconductor region, a third semiconductor layer provided between the first semiconductor layer and the second semiconductor layer, a first electrode layer electrically connected to the first semiconductor layer, and a second electrode layer electrically connected to the second semiconductor layer. The second semiconductor layer and the third semiconductor layer are disposed between the second electrode layer and the first semiconductor layer. The second electrode layer includes a first metal region contacting the first semiconductor region and including silver, a second metal region contacting the second semiconductor region and including silver, and an intermediate metal film including at least one of nickel, aluminum, or titanium. The first metal region is disposed between the first semiconductor region and at least a portion of the intermediate metal film. A distance between the first metal region and the first electrode layer is shorter than a distance between the second metal region and the first electrode layer. The first metal region has a first average grain size, and the second metal region has a second average grain size smaller than the first average grain size.

According to another embodiment, a method for manufacturing a semiconductor light emitting element is disclosed. The method can form a first metal film on a first semiconductor region of a second semiconductor layer of a stacked body, and perform a first heat treatment of the first metal film in an atmosphere including nitrogen. The first metal film includes silver. The stacked body includes a first semiconductor layer of a first conductivity type including a first semiconductor portion and a second semiconductor portion, the second semiconductor layer of a second conductivity type being separated from the first semiconductor portion in a first direction intersecting a direction from the first semiconductor portion toward the second semiconductor portion, and a third semiconductor layer provided between the first semiconductor portion and the second semiconductor layer. The method can form a second metal film on at least a portion of the first metal film and on a second semiconductor region of the second semiconductor layer, and perform a second heat treatment of the second metal film in an atmosphere including oxygen. The second metal film includes silver.

Various embodiments will be described hereinafter with reference to the accompanying drawings.

The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In the drawings and the specification of the application, components similar to those described in regard to a drawing thereinabove are marked with like reference numerals, and a detailed description is omitted as appropriate.

### First Embodiment

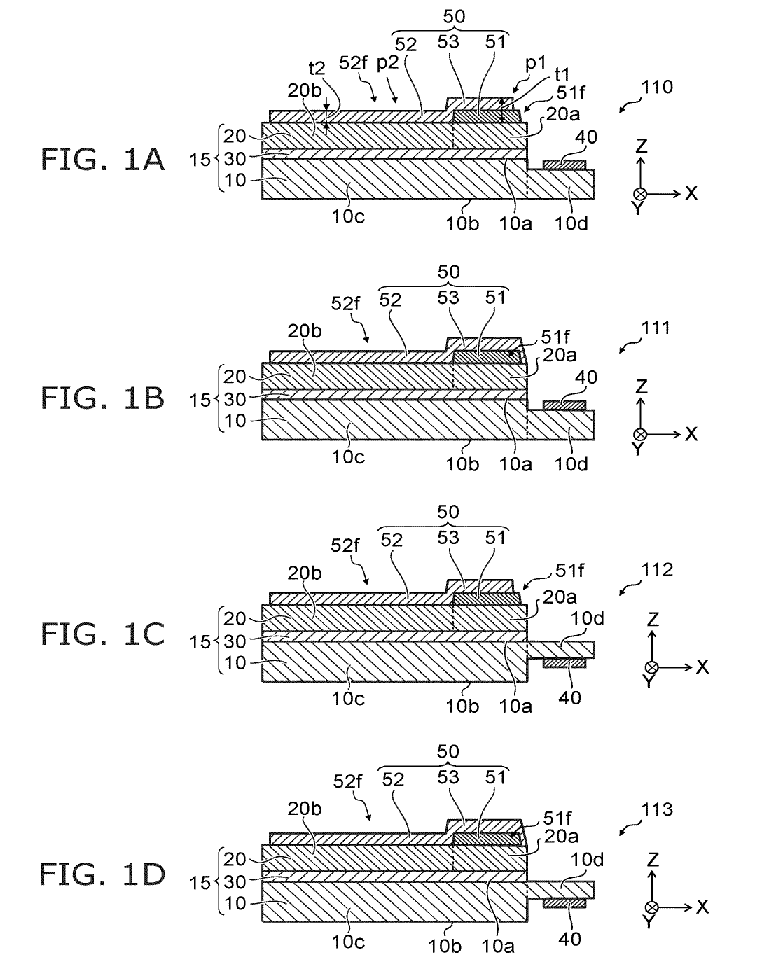

FIG. 1A to FIG. 1D are schematic cross-sectional views illustrating a semiconductor light emitting element according to a first embodiment.

As shown in FIG. 1A, the semiconductor light emitting element 110 according to the embodiment includes a first semiconductor layer 10, a second semiconductor layer 20, a third semiconductor layer 30, a first electrode layer 40, and a second electrode layer 50.

The first semiconductor layer 10 has a first conductivity type. The first conductivity type is, for example, an n-type.

The second semiconductor layer 20 has a second conductivity type. The second conductivity type is, for example, a p-type.

The third semiconductor layer 30 is provided between the first semiconductor layer 10 and the second semiconductor layer 20. The third semiconductor layer 30 is, for example, an active layer. The third semiconductor layer 30 includes a light emitting unit. The semiconductor layers include, for example, nitride semiconductors. Thus, a stacked body 15 that includes the first semiconductor layer 10, the second semiconductor layer 20, and the third semiconductor layer 30 is provided.

The first electrode layer 40 is electrically connected to the first semiconductor layer 10. The second electrode layer 50 is electrically connected to the second semiconductor layer 20.

The second semiconductor layer 20 and the third semiconductor layer 30 are disposed between the second electrode layer 50 and the first semiconductor layer 10.

The direction (a stacking direction) from the first semiconductor layer 10 toward the second semiconductor layer 20 is taken as a Z-axis direction. One direction perpendicular to the Z-axis direction is taken as an X-axis direction. A direction perpendicular to the Z-axis direction and the X-axis direction is taken as a Y-axis direction.

The second electrode layer 50 includes a first metal region 51, a second metal region 52, and a third metal region 53. The first metal region 51, the second metal region 52, and the third metal region 53 include silver. Other than silver, the first metal region 51, the second metal region 52, and the third metal region 53 may further include other metallic elements. In the case where the other metallic elements are included, the concentration of the other metallic elements is 5 atomic % or less.

The first metal region 51 contacts a first semiconductor region 20a of the second semiconductor layer 20. The first semiconductor region 20a is disposed between the first metal region 51 and the third semiconductor layer 30.

The second metal region 52 contacts a second semiconductor region 20b of the second semiconductor layer 20. The second semiconductor region 20b is disposed between the second metal region 52 and the third semiconductor layer 30.

The third metal region 53 contacts the first metal region 51. The first metal region 51 is disposed between the third metal region 53 and the first semiconductor region 20a.

The first semiconductor region 20a of the second semiconductor layer 20 is proximal to the first electrode layer 40. The second semiconductor region 20b of the second semiconductor layer 20 is distal to the first electrode layer 40. For example, when projected onto the X-Y plane, the first semiconductor region 20a is disposed between the second semiconductor region 20b and the first electrode layer 40. The distance between the first semiconductor region 20a and the first electrode layer 40 is shorter than the distance between the second semiconductor region 20b and the first electrode layer 40.

For example, at least a portion of the first metal region 51 is disposed between the second metal region 52 and the first electrode layer 40 when projected onto the X-Y plane (a plane intersecting a first direction from the first semiconductor layer 10 toward the second semiconductor layer 20).

For example, the distance between the first metal region 51 and the first electrode layer 40 is shorter than the distance between the second metal region 52 and the first electrode layer 40.

In other words, the first metal region 51 of the second electrode layer 50 is proximal to the first electrode layer 40. The second metal region 52 of the second electrode layer 50 is distal to the first electrode layer 40. The third metal region 53 is provided on at least a portion of the first metal region 51.

For example, as described below, the first metal region 51 is formed of a first metal film 51f. The second metal region 52 and the third metal region 53 are formed of a second metal film 52f. The second metal film 52f includes a portion contacting the second semiconductor layer 20; and this portion is used as the second metal region 52. A portion of the second metal film 52f is provided on the first metal film 51f; and this portion is used as the third metal region 53. A boundary between the first metal film 51f and the second metal film 52f may or may not be observed.

In the example, the first semiconductor layer 10 includes a first semiconductor portion 10c and a second semiconductor portion 10d. For example, the second semiconductor portion 10d is arranged with the first semiconductor portion 10c in the X-axis direction (a second direction intersecting the first direction (the Z-axis direction) from the first semiconductor layer 10 toward the second semiconductor layer 20). The second semiconductor layer 20 and the third semiconductor layer 30 are disposed between the first semiconductor portion 10c and the second electrode layer 50. The first electrode layer 40 is connected to the second semiconductor portion 10d.

Thus, the first semiconductor layer 10 that includes the first semiconductor portion 10c and the second semiconductor portion 10d is provided in the stacked body 15. The second semiconductor layer 20 is separated from the first semiconductor portion 10c in the first direction (the Z-axis direction) intersecting the direction (e.g., the X-axis direction) from the first semiconductor portion 10c toward the second semiconductor portion 10d. The third semiconductor layer 30 is provided between the first semiconductor portion 10c and the second semiconductor layer 20.

For example, the first semiconductor layer 10 has a first surface 10a that is on the third semiconductor layer 30 side, and a second surface 10b that is on the side opposite to the first surface 10a. For example, the first surface 10a contacts the third semiconductor layer 30. In the semiconductor light emitting element 110, the first electrode layer 40 is provided on the first surface 10a.

In the semiconductor light emitting element 110, a portion of the first metal region 51 is not covered with the third metal region 53. In other words, the third metal region 53 and the portion of the first metal region 51 do not overlap in the Z-axis direction.

On the other hand, in another semiconductor light emitting element 111 according to the embodiment as illustrated in FIG. 1B, the first metal region 51 is covered with the third metal region 53. In other words, the first metal region 51 and the third metal region 53 overlap in the Z-axis direction. Otherwise, the semiconductor light emitting element 111 is the same as the semiconductor light emitting element 110.

On the other hand, in other semiconductor light emitting elements 112 and 113 according to the embodiment as illustrated in FIG. 1C and FIG. 1D, the first electrode layer 40 is provided on the second surface 10b of the first semiconductor layer 10. In the semiconductor light emitting element 112, the third metal region 53 and a portion of the first metal region 51 do not overlap in the Z-axis direction. On the other hand, in the semiconductor light emitting element 112, the first metal region 51 and the third metal region 53 overlap in the Z-axis direction. The other components are similar to those of the semiconductor light emitting element 110, and a description is therefore omitted.

An example of the second electrode layer 50 of the semiconductor light emitting element 110 will now be described. The description recited below is applicable to the semiconductor light emitting elements 111 to 113 as well.

The second electrode layer 50 is, for example, a silver electrode (a silver film). Grain boundaries are observed in the silver film. The regions that are partitioned by the grain boundaries are grains. The average value of the grain sizes of the multiple grains is taken as the average grain size.

The first metal region 51 of the second electrode layer 50 has a first average grain size. The second metal region 52 has a second average grain size. The third metal region 53 has a third average grain size. The second average grain size is smaller than the first average grain size. The third average grain size is smaller than the first average grain size.

For example, the first average grain size is 0.205 micrometers (μm) or more. The second average grain size is less than 0.205 μm. The third average grain size is less than 0.205 μm. For example, the first average grain size is not less than 0.205 μm and not more than 0.30 μm. For example, the first average grain size is about 0.21 to about 0.28 μm.

On the other hand, the second average grain size is not less than 0.18 μm and not more than 0.195 μm. For example, the second average grain size is about 0.19 μm. The third average grain size is not less than 0.18 μm and not more than 0.195 μm. For example, the third average grain size is about 0.19 μm.

The inventor of the application discovered that the average grain size is changed by heating the silver film formed on the semiconductor layer at various conditions. Also, the contact resistance between the semiconductor layer and the silver film changes due to the heating conditions. The light reflectance of the silver film contacting the semiconductor layer also changes due to the heating conditions.

Experiments performed by the inventor of the application will now be described.

A silver film is formed on a p-type GaN layer (corresponding to the second semiconductor layer 20) including Mg; and heat treatment (annealing) is performed at various conditions. The grain sizes of the multiple grains inside the silver film are evaluated by electron back-scatter diffraction (EBSD) for the samples that are made. The boundary lines between grains having an orientation difference of 5 degrees or more are defined as the grain boundaries. The grain boundaries corresponding to Σ3 also are considered to be grain boundaries. The grain size is defined as the diameter of a circle having a surface area equal to the surface area of the grain. The average value of the grain sizes is the average grain size.

Annealing is implemented in an atmosphere including nitrogen or in an atmosphere including oxygen. In the atmosphere including nitrogen, the concentration of nitrogen is not less than 96% and not more than 100%; and the concentration of oxygen is 4% or less. On the other hand, in the atmosphere including oxygen, the concentration of oxygen is not less than 5% and not more than 100%; and the concentration of nitrogen is 95% or less. A sample is made in which annealing is performed in the atmosphere including oxygen after the annealing in the atmosphere including nitrogen. The annealing time is one minute.

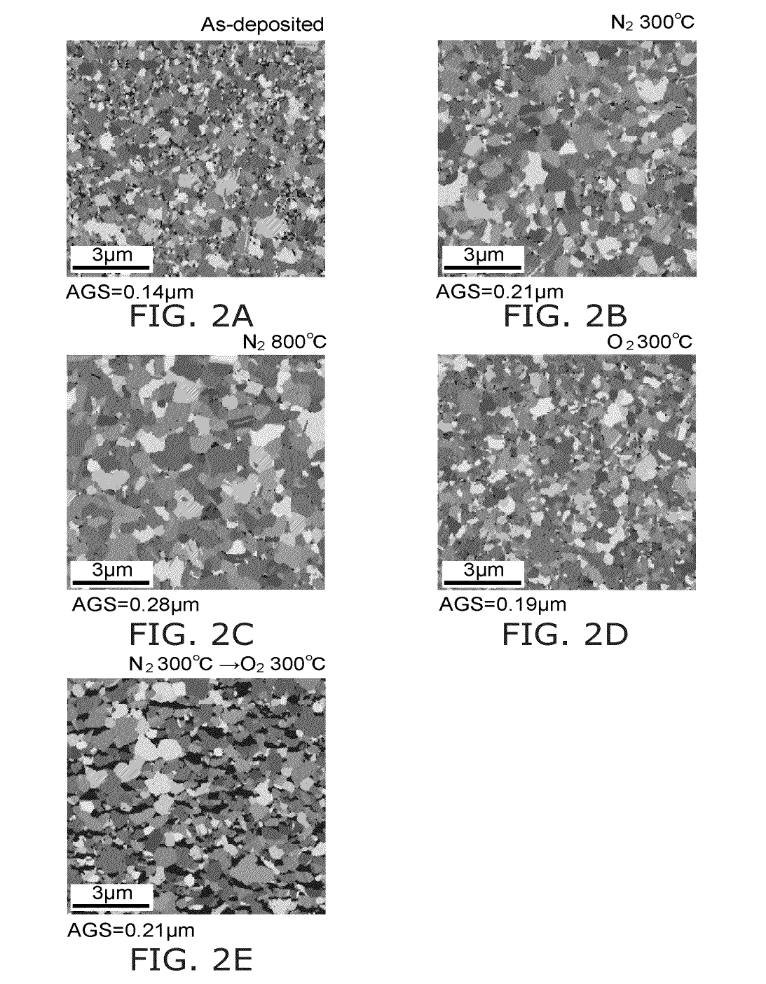

FIG. 2A to FIG. 2E are schematic views illustrating a characteristic of the semiconductor light emitting element.

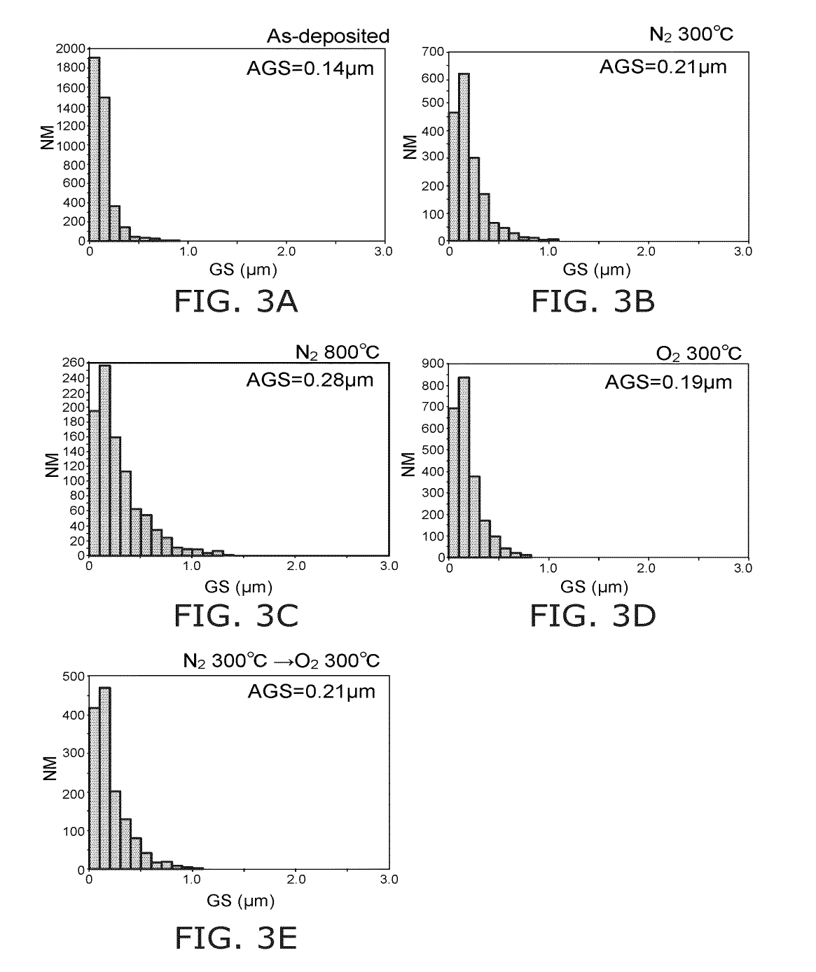

These drawings illustrate EBSD crystal grain maps of the silver film for different annealing conditions. FIG. 3A to FIG. 3E are graphs of the characteristic of the semiconductor light emitting element.

FIG. 3A to FIG. 3E correspond respectively to the samples of FIG. 2A to FIG. 2E. In these figures, the horizontal axis is a grain size GS (μm). The vertical axis is a number of grains NM corresponding to the grain size GS.

As shown in FIG. 2A, the grain size is relatively small for the sample “As-deposited” that is not annealed. From the analysis result of FIG. 3A, an average grain size AGS is calculated to be about 0.14 μm.

As shown in FIG. 2B, the grain size is larger for the sample “N₂ 300° C.” that is annealed at 300° C. in the atmosphere including nitrogen compared to the sample that is not annealed. From the analysis result of FIG. 3B, the average grain size AGS is calculated to be about 0.21 μm.

As shown in FIG. 2C, the grain size is even larger for the sample “N₂ 800° C.” that is annealed at 800° C. in the atmosphere including nitrogen. From the analysis result of FIG. 3C, the average grain size AGS is calculated to be about 0.28 μm.

As shown in FIG. 2D, the grain size is small for the sample “O₂ 300° C.” that is annealed at 300° C. in the atmosphere including oxygen. From the analysis result of FIG. 3D, the average grain size AGS is calculated to be about 0.19 μm.

As shown in FIG. 2E, the grain size for the sample “N₂ 300° C.→O₂ 300° C.” that is annealed at 300° C. in the atmosphere including oxygen after the annealing at 300° C. in the atmosphere including nitrogen is substantially the same as that of the sample “N₂ 300° C.” From the analysis result of FIG. 3E, the average grain size AGS is calculated to be about 0.21 μm.

Thus, a relatively large grain size is observed for the annealing in the atmosphere including nitrogen. The average grain size AGS for the annealing in the atmosphere including nitrogen is not less than about 0.205 μm and not more than 0.30 μm for the evaluations of multiple samples. On the other hand, relatively small grain sizes are observed for the annealing in the atmosphere including oxygen. The average grain size of the annealing in the atmosphere including oxygen is not less than 0.18 μm but less than 0.195 μm for the evaluations of multiple samples.

It can be seen that the grain size for the annealing in the atmosphere including oxygen after the annealing in the atmosphere including nitrogen is equal to the grain size for the annealing in the atmosphere including nitrogen. In other words, it is considered that the average grain size is determined by the conditions of the initial annealing.

Evaluation results of the contact resistance will now be described.

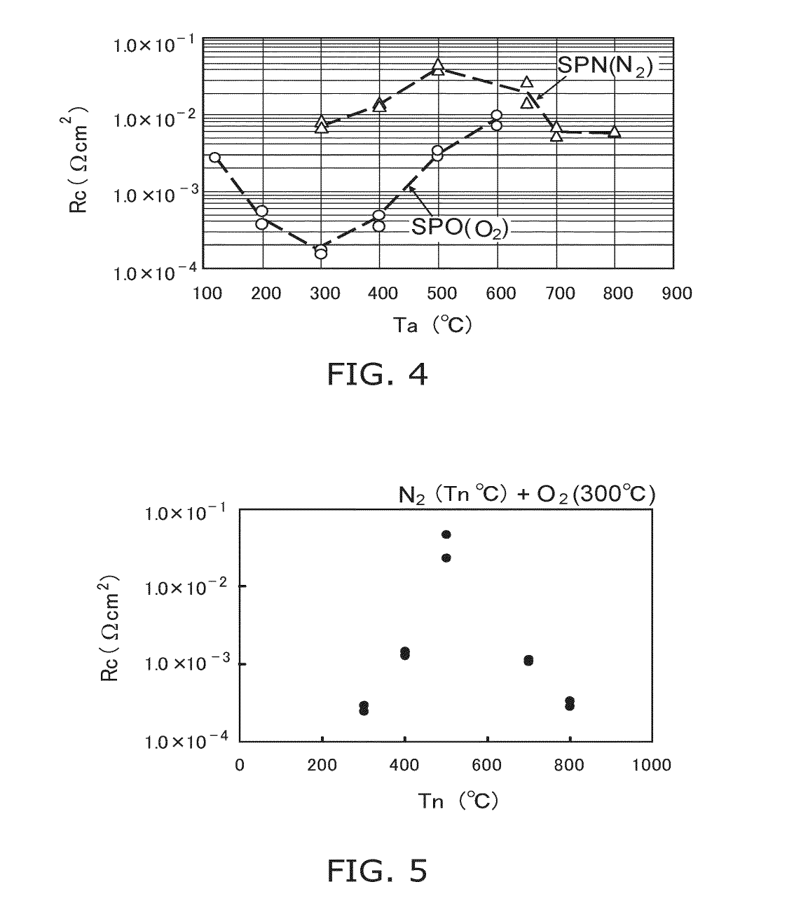

FIG. 4 is a graph of a characteristic of the semiconductor light emitting element.

The horizontal axis is a temperature Ta (° C.) of the annealing. The vertical axis is a contact resistance Rc (Ωcm²) between the p-type GaN layer (the second semiconductor layer 20) and the silver film. The contact resistance Rc is the specific contact resistivity.

FIG. 4 shows an oxygen annealing sample group SPO that is annealed in the atmosphere including oxygen and a nitrogen annealing sample group SPN that is annealed in the atmosphere including nitrogen. The contact resistance Rc is about 3×10⁻³ Ωcm² for a sample that is not annealed.

As shown in FIG. 4, the contact resistance Rc of the nitrogen annealing sample group SPN in which the silver film is annealed in the atmosphere including nitrogen is not less than 5×10⁻³ Ωcm² and not more than 1×10⁻¹ Ωcm². On the other hand, the contact resistance Rc of the oxygen annealing sample group SPO in which the silver film is annealed in the atmosphere including oxygen is not less than 1.5×10⁻⁴ Ωcm² and not more than 5×10⁻⁴ Ωcm² when the temperature Ta is 200° C. to 400° C.

In other words, the contact resistance Rc for the annealing in the atmosphere including oxygen in which the temperature Ta of the annealing is 200° C. to 400° C. is lower than the contact resistance for the annealing in the atmosphere including nitrogen.

For the annealing in the atmosphere including oxygen, when the temperature Ta of the annealing exceeds 500° C., the flatness of the silver film degrades; and holes form.

FIG. 5 is a graph of a characteristic of the semiconductor light emitting element.

FIG. 5 shows the contact resistance Rc of samples in which the silver film is annealed at 300° C. in the atmosphere including oxygen after the annealing in the atmosphere including nitrogen. The horizontal axis is a temperature Tn (° C.) of the annealing in the atmosphere including nitrogen; and the vertical axis is the contact resistance Rc.

It can be seen from FIG. 5 that the contact resistance Rc is not less than 2.5×10⁻⁴ Ωcm² and not more than 1.5×10⁻³ Ωcm² when the temperature Tn of the annealing in the atmosphere including nitrogen is not less than 700° C. and not more than 800° C. or when the temperature Tn of the annealing in the atmosphere including nitrogen is not less than 300° C. and not more than 400° C. The contact resistance Rc is high and is about 2.0×10⁻² Ωcm² or more when the temperature Tn of the annealing in the atmosphere including nitrogen is not less than 500° C. and not more than 600° C.

In other words, as illustrated in FIG. 4, the contact resistance increases for the annealing in the atmosphere including nitrogen; but the contact resistance Rc decreases for the annealing at not less than 300° C. and not more than 400° C. in the atmosphere including oxygen after the annealing in the atmosphere including nitrogen.

Evaluation results of the reflectance will now be described.

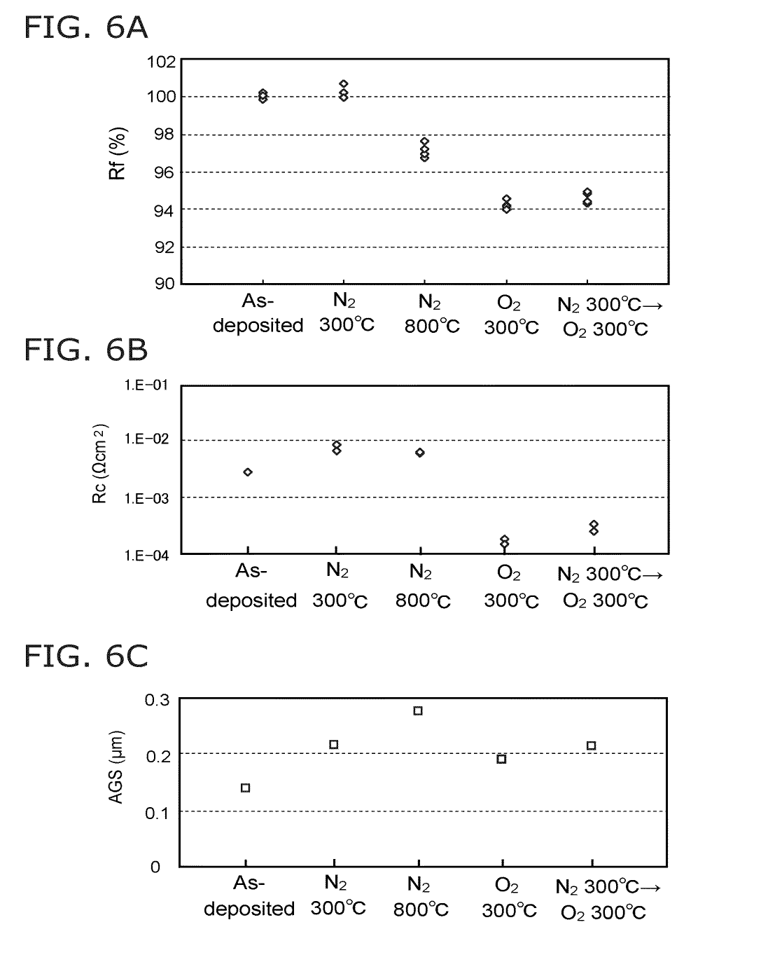

FIG. 6A to FIG. 6C are graphs of characteristics of the semiconductor light emitting element.

FIG. 6A shows the reflectance for the samples of the various annealing conditions. The horizontal axis is the conditions of the samples. The vertical axis is the reflectance Rf (%). FIG. 6B and FIG. 6C show the contact resistance Rc and the average grain size AGS corresponding to FIG. 6A. The vertical axis of FIG. 6B is the contact resistance Rc. The vertical axis of FIG. 6C is the average grain size AGS of the grains of the silver film.

As shown in FIG. 6A, the reflectance Rf of the sample “As-deposited” that is not annealed is taken to be 100%. The reflectance Rf is about 100% for the sample “N₂ 300° C.” that is annealed at 300° C. in the atmosphere including nitrogen. The reflectance Rf is 97% to 98% for the sample “N₂ 800° C.” that is annealed at 800° C. in the atmosphere including nitrogen. The reflectance Rf is about 94% for the sample “O₂ 300° C.” that is annealed at 300° C. in the atmosphere including oxygen. The reflectance Rf is about 94% for the sample “N₂ 300° C. O₂ 300° C.” that is annealed at 300° C. in the atmosphere including oxygen after the annealing at 300° C. in the atmosphere including nitrogen.

On the other hand, as shown in FIG. 6B, for the sample “N₂ 300° C.,” the contact resistance Rc is relatively high and is 7×10⁻³ Ωcm² to 8×10⁻³ Ωcm². For the sample “N₂ 800° C.” as well, the contact resistance Rc is relatively high and is 6×10⁻³ Ωcm² to 7×10⁻³ Ωcm². On the other hand, for the sample “O₂ 300° C.,” the contact resistance Rc is relatively low and is 1.5×10⁻⁴ Ωcm² to 2×10⁻⁴ Ωcm². For the sample “N₂ 300° C.→O₂ 300° C.,” the contact resistance Rc is relatively low and is 2.5×10⁻⁴ Ωcm² to 3×10⁻⁴ Ωcm².

As shown in FIG. 6C, the average grain size AGS is 0.21 μm to 0.28 μm for the sample “N₂ 300° C.” and the sample “N₂ 800° C.” The average grain size AGS is about 0.19 μM for the sample “O₂ 300° C.” The average grain size AGS is about 0.21 μM for the sample “N₂ 300° C.→O₂ 300° C.”

As shown in FIG. 6A, the contact resistance Rc changes due to the annealing conditions. For example, this phenomenon is utilized in the embodiment. Namely, the first metal region 51 of the second electrode layer 50 includes the silver film of the conditions having the high contact resistance Rc. The second metal region 52 of the second electrode layer 50 includes the silver film of the conditions having the low contact resistance Rc. The first metal region 51 is proximal to the first electrode layer 40. By setting the contact resistance Rc of the first metal region 51 to be high, current injection into the second semiconductor layer 20 in this region is suppressed. By setting the contact resistance Rc of the second metal region 52 to be low, the current injection into the second semiconductor layer 20 in this region is promoted. By using such a configuration, the uniformity of the light emission can be increased.

For example, first, the first metal film 51f that is used to form the first metal region 51 is formed on the second semiconductor layer 20. Then, the high contact resistance Rc and the high reflectance Rf are obtained by annealing at a temperature of, for example, 300° C. to 800° C. in, for example, an atmosphere including nitrogen. Subsequently, the second metal film 52f that is used to form the second metal region 52 is formed on the second semiconductor layer 20. Then, for example, annealing is performed at a temperature of 200° C. to 400° C. in an atmosphere including oxygen. Thereby, a low contact resistance Rc is obtained. Although the reflectance Rf at this time is low compared to that of the annealing in the atmosphere including nitrogen, this is practically not a problem. Thereby, the contact resistance of the first metal region 51 can be set to be higher than the contact resistance Rc of the second metal region 52. Thereby, the uniformity of the light emission can be increased.

However, in the case where the method recited above is used, annealing in the atmosphere including oxygen is further performed for the first metal region 51 annealed in the atmosphere including nitrogen. Therefore, this region has the characteristics of the sample “N₂ 300° C.→O₂ 300° C.” For such conditions, as shown in FIG. 6A, the contact resistance Rc decreases to be equal to that of the annealing in the atmosphere including oxygen. Therefore, the target difference between the contact resistances cannot be formed.

However, the high contact resistance Rc can be maintained for the silver film of the first metal region 51 by further forming a silver film on the first metal region 51 annealed in the atmosphere including nitrogen and by annealing the stacked film in oxygen.

For example, the high contact resistance Rc can be maintained for the silver film of the first metal region 51 by forming a silver film of about 200 nm (not less than 150 nm and not more than 250 nm) on the silver film of the first metal region 51 annealed in the atmosphere including nitrogen and by annealing the stacked film in oxygen.

It is considered that this is because the oxygen that reaches the interface between the first metal region 51 and the second semiconductor layer 20 is suppressed by the silver film of the upper side formed on the silver film of the first metal region 51. Or, it is considered that the oxygen that penetrates the first metal region 51 is suppressed by the silver film of the upper side. In other words, the silver film of the first metal region 51 is protected by the silver film of the upper side.

In the embodiment, the third metal region 53 corresponds to the silver film of the upper side provided on the silver film of the first metal region 51. In other words, the first metal region 51, the second metal region 52, and the third metal region 53 recited above are provided in the second electrode layer 50. The first average grain size of the first metal region 51 is set to be 0.205 micrometers (μm) or more. For example, this corresponds to the silver film formed by the annealing in the atmosphere including nitrogen. The second average grain size of the second metal region 52 is set to be less than 0.205 μm. This corresponds to the silver film formed by the annealing in the atmosphere including oxygen. The third average grain size of the third metal region 53 provided on the first metal region 51 is less than 0.205 μm. This is the silver film formed by the annealing in the atmosphere including oxygen. Because the third metal region 53 is provided on the first metal region 51, a high contact resistance Rc of the first metal region 51 that is annealed in the atmosphere including nitrogen can be maintained. The contact resistance Rc of the second metal region 52 is lower than that of the annealing in the atmosphere including oxygen. Thereby, the uniformity of the light emission can be increased.

For example, the contact resistance Rc between the first metal region 51 and the second semiconductor layer 20 (the first semiconductor region 20a) is 5×10⁻³ Ωcm² or more. The contact resistance Rc between the first metal region 51 and the second semiconductor layer 20 (the first semiconductor region 20a) is, for example, 5.0×10⁻² Ωcm² or less. The contact resistance Rc between the first metal region 51 and the second semiconductor layer 20 (the first semiconductor region 20a) may be 1×10⁻¹ Ωcm² or less. On the other hand, for example, the contact resistance Rc between the second metal region 52 and the second semiconductor layer 20 (the second semiconductor region 20b) is not less than 1.5×10⁻⁴ Ωcm² and not more than 5.0×10⁻⁴ Ωcm².

The silver film of the first metal region 51 is set to be practically about 200 nm (not less than 150 nm and not more than 250 nm). Thereby, good patternability is obtained.

Accordingly, it is favorable for the thickness of the silver film of the upper side on the silver film of the first metal region 51 to be not less than about ½ of the thickness of the silver film of the first metal region 51 and not more than about twice the thickness of the silver film of the first metal region 51.

Thus, in the embodiment, the contact resistance between the first metal region 51 and the first semiconductor region 20a is higher than the contact resistance between the second metal region 52 and the second semiconductor region 20b. Thereby, the uniformity of the light emission can be increased. On the other hand, the reflectance of the first metal region 51 is higher than the reflectance of the second metal region 52.

As shown in FIG. 1A, the second electrode layer 50 includes a first portion p1 and a second portion p2. The first portion p1 includes the first metal region 51 and the third metal region 53. The second portion p2 includes the second metal region 52. The first portion p1 is the portion of the second electrode layer 50 having a thick thickness. The second portion p2 is the portion of the second electrode layer 50 having a thin thickness. The first portion p1 has a first thickness t1 along the Z-axis direction (the first direction from the first semiconductor layer 10 toward the second semiconductor layer 20). The second portion p2 has a second thickness t2 along the Z-axis direction. The first thickness t1 is thicker than the second thickness t2. The first thickness t1 is, for example, not less than 225 nm and not more than 750 nm. The second thickness t2 is, for example, not less than 75 nm and not more than 500 nm.

The absolute value of the difference between the first thickness t1 and the second thickness t2 is not less than ½ of the second thickness t2 and not more than twice the second thickness t2. For example, the absolute value of the difference between the first thickness t1 and the second thickness t2 may be substantially the same as the second thickness t2. For example, the second metal film 52f that is used to form the second metal region 52 extends onto the first metal region 51. The extended portion is used to form the third metal region 53.

In the embodiment, the first average grain size is the average grain size obtained by electron back-scatter diffraction of a surface area of 10 square micrometers of the first metal region 51. The second average grain size is the average grain size obtained by electron back-scatter diffraction of a surface area of 10 square micrometers of the second metal region 52. The third average grain size is the average grain size obtained by electron back-scatter diffraction of a surface area of 10 square micrometers of the third metal region 53.

In the embodiment, for example, the surface area of the third metal region 53 in the X-Y plane (in a plane perpendicular to the first direction which is the stacking direction) is not less than 0.8 times the surface area of the first metal region 51 in the X-Y plane. For example, in the case where the surface area of the third metal region 53 is excessively small compared to the surface area of the first metal region 51, the surface area of the first metal region 51 not covered with the third metal region 53 increases. Therefore, the region of the first metal region 51 where the contact resistance Rc is low increases due to the annealing in the atmosphere including oxygen. In the case where the surface area of the third metal region 53 is not less than 0.8 times the surface area of the first metal region 51, a low contact resistance Rc of the first metal region 51 can be maintained.

An example of the stacked body 15 will now be described.

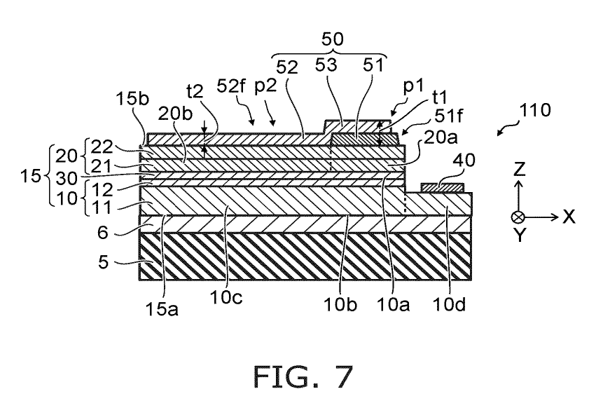

FIG. 7 is a schematic cross-sectional view illustrating the semiconductor light emitting element according to the first embodiment.

As shown in FIG. 7, the first semiconductor layer 10 includes, for example, a first n-side layer 11 and a second n-side layer 12. The second n-side layer 12 is provided between the first n-side layer 11 and the third semiconductor layer 30. The first n-side layer 11 functions as an n-type contact layer. The second n-side layer 12 functions as an n-type guide layer. The first n-side layer 11 includes, for example, a GaN layer to which a high concentration of an n-type impurity (e.g., silicon, etc.) is added, etc. The second n-side layer 12 includes, for example, a GaN layer to which an n-type impurity having a concentration lower than that of the first n-side layer 11 is added, etc.

The second semiconductor layer 20 includes a first p-side layer 21 and a second p-side layer 22. The first p-side layer 21 is provided between the second p-side layer 22 and the third semiconductor layer 30. For example, the first p-side layer 21 functions as an electron overflow prevention layer (a suppression layer). The second p-side layer 22 functions as a p-type contact layer. The first p-side layer 21 includes, for example, an AlGaN layer to which a p-type impurity (e.g., magnesium) is added, etc. The second p-side layer 22 includes a GaN layer to which a high concentration of a p-type impurity is added, etc.

The stacked body 15 has a first major surface 15a and a second major surface 15b. The second major surface 15b is on the side opposite to the first major surface 15a. The first major surface 15a is the surface on the first semiconductor layer 10 side. The second major surface 15b is the surface on the second semiconductor layer 20 side. In the semiconductor light emitting element 110, the first electrode layer 40 and the second electrode layer 50 are provided on the second major surface 15b. In the semiconductor light emitting element 111 shown in FIG. 1B as well, the first electrode layer 40 and the second electrode layer 50 are provided on the second major surface 15b. In the semiconductor light emitting elements 112 and 113 shown in FIG. 1C and FIG. 1D as well, the first electrode layer 40 is provided on the first major surface 15a; and the second electrode layer 50 is provided on the second major surface 15b.

For example, a buffer layer 6 is provided on a substrate 5 for the crystal growth of sapphire. The stacked body 15 is provided on the buffer layer 6. For example, metal-organic chemical vapor deposition (MOCVD) or the like is used to form these layers. A semiconductor stacked unit that is used to form the stacked body 15 is sequentially grown. Subsequently, for example, the semiconductor stacked unit is patterned to expose a portion of the first semiconductor layer 10; and the first electrode layer 40 is formed on the first semiconductor layer 10. The first electrode layer 40 includes, for example, a stacked film of a Ti film, a Pt film, and a Au film. A silver film that is used to form the second electrode layer 50 is formed on the second p-side layer 22 (the p-type contact layer) of the semiconductor stacked unit.

A current is supplied to the third semiconductor layer 30 via the first semiconductor layer 10 and the second semiconductor layer 20 by a voltage applied between the first electrode layer 40 and the second electrode layer 50; and light (emitted light) is emitted from the third semiconductor layer 30. For example, the third semiconductor layer 30 emits at least one of ultraviolet, violet, blue, or green light. In other words, the wavelength (the dominant wavelength) of the light emitted from the third semiconductor layer 30 is not less than 360 nanometers (nm) and not more than 580 nm.

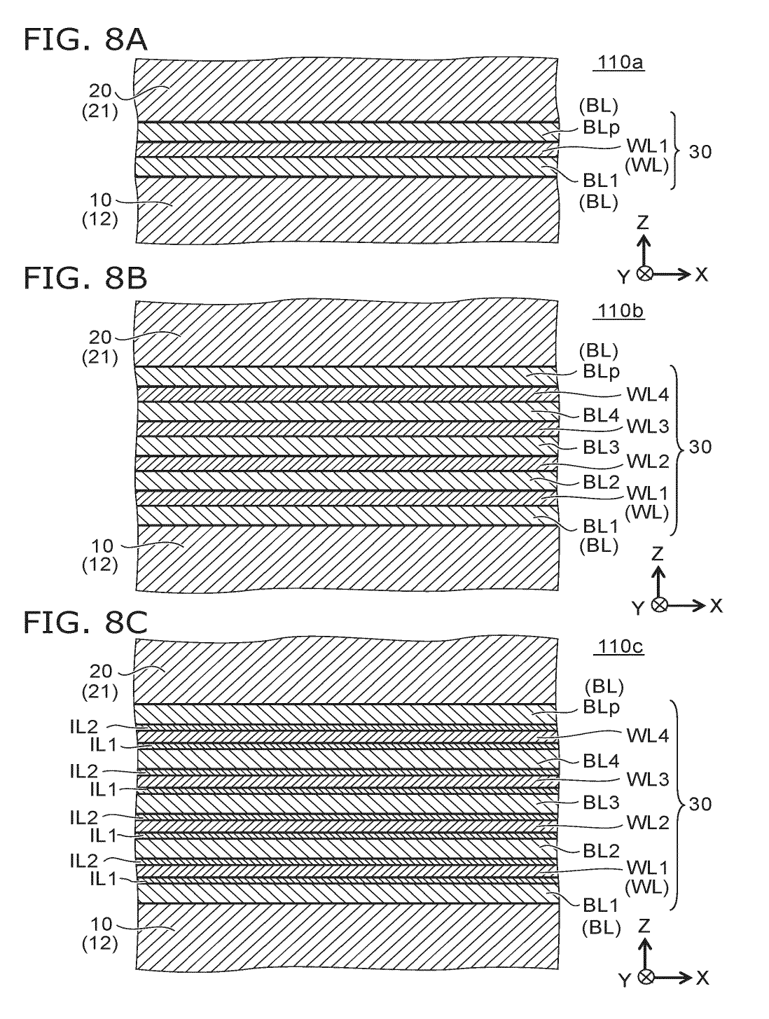

FIG. 8A to FIG. 8C are schematic cross-sectional views illustrating portions of semiconductor light emitting elements according to the first embodiment.

These drawings are schematic views illustrating examples of the configuration of the third semiconductor layer 30.

In a semiconductor light emitting element 110a according to the embodiment as shown in FIG. 8A, the third semiconductor layer 30 has a SQW structure. Namely, the third semiconductor layer 30 includes a barrier layer BL (a first barrier layer BL1), a p-side barrier layer BLp, and a well layer WL (a first well layer WL1) provided between the first barrier layer BL1 and the p-side barrier layer BLp.

In a semiconductor light emitting element 110b according to the embodiment as shown in FIG. 8B, the third semiconductor layer 30 has a MQW structure. Namely, the third semiconductor layer 30 includes multiple barrier layers (in the example, first to fourth barrier layers BL1 to BL4 and the p-side barrier layer BLp) stacked along the Z-axis direction and well layers (first to fourth well layers WL1 to WL4) provided respectively between the multiple barrier layers. Although four layers of well layers are provided in this specific example, the number of well layers is arbitrary.

Thus, the third semiconductor layer 30 further includes the Nth barrier layer provided on the side of the (N−1)th well layer WL opposite to the (N−1)th barrier layer, and the Nth well layer provided on the side of the Nth barrier layer opposite to the (N−1)th well layer, where N is an integer not less than 2.

In a semiconductor light emitting element 110c according to the embodiment as shown in FIG. 8C, the third semiconductor layer 30 further includes intermediate layers provided respectively in the regions between the barrier layers and the well layers. In other words, the third semiconductor layer 30 further includes a first intermediate layer IL1 that is provided between the (N−1)th barrier layer and the (N−1)th well layer, and a second intermediate layer IL2 that is provided between the (N−1)th well layer and the Nth barrier layer. The second intermediate layer IL2 is provided between the Nth well layer and the p-side barrier layer BLp. The first intermediate layer IL1 and the second intermediate layer IL2 are provided as necessary and are omissible. The first intermediate layer IL1 may be provided, and the second intermediate layer IL2 may be omitted. The second intermediate layer IL2 may be provided, and the first intermediate layer IL1 may be omitted.

The barrier layer (e.g., the first to fourth barrier layers BL1 to BL4 and the Nth barrier layer) includes, for example, Inₓ₁Al_{y1}Ga_{1-x1-y1}N (0≦x1<1, 0≦y1<1, and x1+y1≦1). The barrier layer includes, for example, In_{0.02}Al_{0.33}Ga_{0.65}N. The thickness of the barrier layer is, for example, not less than 5 nm and not more than 15 nm, e.g., about 12.5 nm.

The p-side barrier layer BLp includes, for example, Inₓ₂Al_{y2}Ga_{1-x2-y2}N (0≦x2<1, 0≦y2<1, and x2+y2≦1). The p-side barrier layer BLp includes, for example, In_{0.02}Al_{0.033}Ga_{0.65}N. The thickness of the p-side barrier layer BLp is, for example, not less than 5 nm and not more than 15 nm, e.g., about 12.5 nm.

The well layer (e.g., the first to fourth well layers WL1 to WL4 and the Nth well layer) includes, for example, Inₓ₃Al_{y3}Ga_{1-x3-y3}N (0<x3≦1, 0≦y3<1, and x3+y3≦1). The well layer includes, for example, In_{0.15}Ga_{0.85}N. The thickness of the well layer is, for example, not less than 1.5 nm and not more than 4 nm, e.g., about 2.5 nm.

The composition ratio of In (the proportion in the Group III elements of the number of atoms of In) included in the well layer is higher than the composition ratio of In (the proportion in the Group III elements of the number of atoms of In) included in the barrier layer (the first to fourth barrier layers BL1 to BL4, the Nth barrier layer, and the p-side barrier layer BLp). Thereby, the bandgap energy of the barrier layer is larger than the bandgap energy of the well layer.

The first intermediate layer IL1 includes, for example, Inₓ₄Ga₁₋ₓ₄N (0≦x4<1). The first intermediate layer IL1 includes, for example, In_{0.02}Ga_{0.98}N. The thickness of the first intermediate layer IL1 is, for example, 0.5 nm.

The second intermediate layer IL2 includes, for example, Inₓ₅Ga₁₋ₓ₅N (0≦x5<1). The second intermediate layer IL2 includes, for example, In_{0.02}Ga_{0.98}N. The thickness of the second intermediate layer IL2 is, for example, 0.5 nm.

The composition ratio of In (the proportion in the Group III elements of the number of atoms of In) included in the well layer is higher than the composition ratio of In (the proportion in the Group III elements of the number of atoms of In) included in the first intermediate layer IL1 and the second intermediate layer IL2. Thereby, the bandgap energies of the first intermediate layer IL1 and the second intermediate layer IL2 are larger than the bandgap energy of the well layer. The first intermediate layer IL1 may be considered to be a portion of the barrier layer. The second intermediate layer IL2 may be considered to be a portion of the barrier layer. In other words, the barrier layer that is stacked with the well layer may include multiple layers having different compositions.

The first intermediate layer IL1 and the second intermediate layer IL2 may be provided in the SQW structure illustrated in FIG. 8A. In such a case, the first intermediate layer IL1 is provided between the first barrier layer BL1 and the first well layer WL1; and the second intermediate layer IL2 is provided between the first well layer WL1 and the p-side barrier layer BLp.

In the embodiment, the configuration of the third semiconductor layer 30 is not limited to those recited above; and various modifications are possible for the materials and thicknesses of the barrier layer, the p-side barrier layer BLp, the well layer, the first intermediate layer ILL and the second intermediate layer IL2. As recited above, the barrier layer, the p-side barrier layer BLp, the well layer, the first intermediate layer IL1, and the second intermediate layer IL2 include nitride semiconductors.

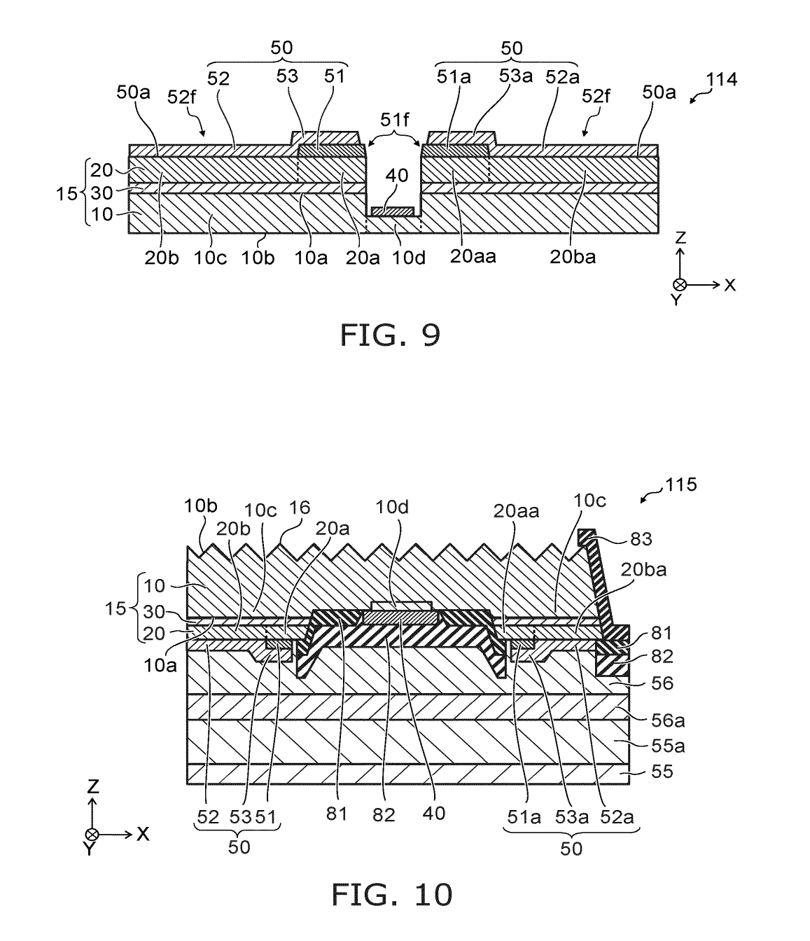

FIG. 9 is a schematic cross-sectional view illustrating another semiconductor light emitting element according to the first embodiment.

As shown in FIG. 9, the stacked body 15 (the first semiconductor layer 10, the second semiconductor layer 20, and the third semiconductor layer 30), the first electrode layer 40, and the second electrode layer 50 are provided in the semiconductor light emitting element 114 according to the embodiment as well. The second semiconductor layer 20 includes the first semiconductor region 20a and the second semiconductor region 20b. The first metal region 51, the second metal region 52, and the third metal region 53 are provided in the second electrode layer 50. In the example, the second semiconductor layer 20 further includes a third semiconductor region 20aa and a fourth semiconductor region 20ba. A fourth metal region 51a, a fifth metal region 52a, and a sixth metal region 53a are further provided in the second electrode layer 50. Otherwise, the semiconductor light emitting element 114 is similar to the semiconductor light emitting element 110, and a description is therefore omitted.

The first semiconductor region 20a is disposed between the second semiconductor region 20b and the fourth semiconductor region 20ba. The third semiconductor region 20aa is disposed between the first semiconductor region 20a and the fourth semiconductor region 20ba.

The first electrode layer 40 is positioned between the first semiconductor region 20a and the third semiconductor region 20aa in the direction (e.g., the X-axis direction) from the second semiconductor region 20b toward the fourth semiconductor region 20ba.

The fourth metal region 51a, the fifth metal region 52a, and the sixth metal region 53a of the second electrode layer 50 include silver. The fourth metal region 51a contacts the third semiconductor region 20aa. The fifth metal region 52a contacts the fourth semiconductor region 20ba. The sixth metal region 53a contacts the fourth metal region 51a. The fourth metal region 51a is disposed between the sixth metal region 53a and the third semiconductor region 20aa.

The fourth metal region 51a has a fourth average grain size.

The fifth metal region 52a has a fifth average grain size that is smaller than the fourth average grain size.

The sixth metal region 53a has a sixth average grain size that is smaller than the fourth average grain size.

For example, the fourth average grain size is not less than 0.205 μm and not more than 0.30 μm.

The fifth average grain size is not less than 0.18 μm and not more than 0.195 μm.

The sixth average grain size is not less than 0.18 μm and not more than 0.195 μm.

Because the sixth metal region 53a is provided on the fourth metal region 51a, a high contact resistance Rc of the fourth metal region 51a that is annealed in the atmosphere including nitrogen can be maintained. The contact resistance Rc in the fifth metal region 52a is lower than that of the annealing in the atmosphere including oxygen. For example, the contact resistance between the fourth metal region 51a and the third semiconductor region 20aa is higher than the contact resistance between the fifth metal region 52a and the fourth semiconductor region 20ba. Thereby, the uniformity of the light emission can be increased. On the other hand, the reflectance of the fourth metal region 51a is higher than the reflectance of the fifth metal region 52a.

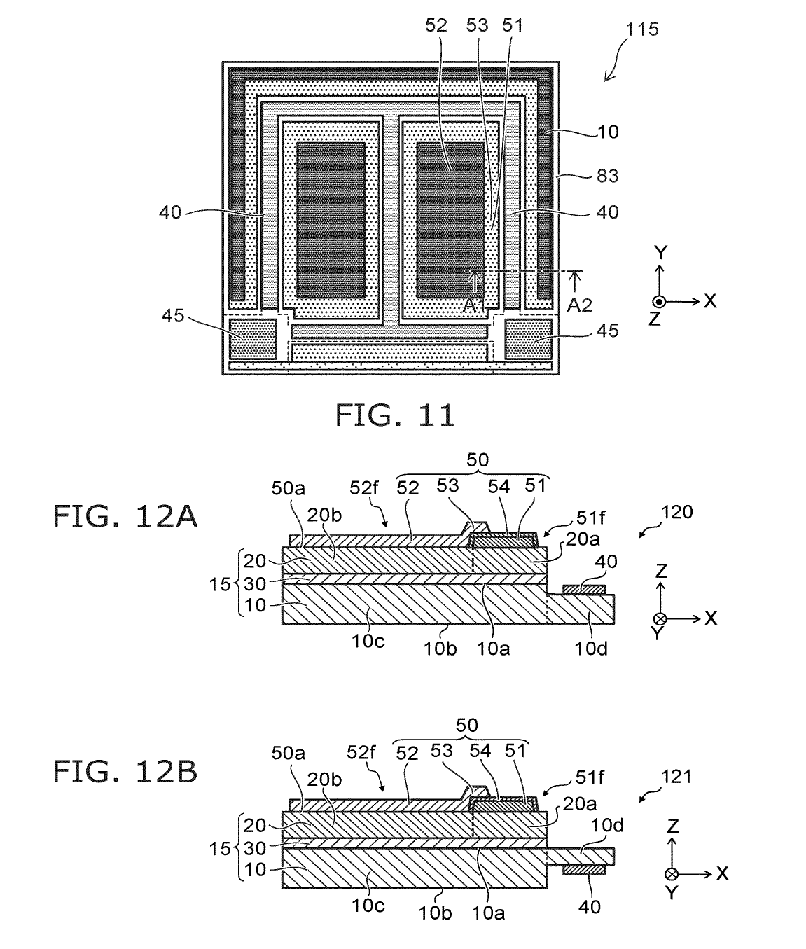

FIG. 10 is a schematic cross-sectional view illustrating another semiconductor light emitting element according to the first embodiment. FIG. 11 is a schematic plan view illustrating the semiconductor light emitting element according to the first embodiment. FIG. 10 is a cross-sectional view along line A1-A2 of FIG. 11.

As shown in FIG. 10, the stacked body 15 (the first semiconductor layer 10, the second semiconductor layer 20, and the third semiconductor layer 30), the first electrode layer 40, and the second electrode layer 50 are provided in the semiconductor light emitting element 115 according to the embodiment as well. The second semiconductor layer 20 includes the first semiconductor region 20a, the second semiconductor region 20b, the third semiconductor region 20aa, and the fourth semiconductor region 20ba. The first metal region 51, the second metal region 52, the third metal region 53, the fourth metal region 51a, the fifth metal region 52a, and the sixth metal region 53a are provided in the second electrode layer 50. The first electrode layer 40 is provided on the first surface 10a of the first semiconductor layer 10.

A base body 55a is provided on an electrode 55. A metal film 56a is provided on the base body 55a. A metal film 56 is provided on the metal film 56a. An insulating layer 82 is provided on a portion of the metal film 56. The second electrode layer 50 is provided on another portion of the metal film 56. The second semiconductor layer 20 and the third semiconductor layer 30 are provided on the second electrode layer 50. The first electrode layer 40 is provided on a portion of the insulating layer 82. An insulating layer 81 is provided on another portion of the insulating layer 82. The first semiconductor layer 10 is provided on the first electrode layer 40, the insulating layer 81, and the third semiconductor layer 30. The lower surface of the first semiconductor layer 10 is used as the first surface 10a. An unevenness 16 is provided in the upper surface (the second surface 10b) of the first semiconductor layer 10. An insulating layer 83 is provided at the side surface (the surface intersecting the Z-axis direction) of the stacked body 15.

As shown in FIG. 11, the first electrode layer 40 has a fine wire configuration. A pad 45 is provided to be electrically connected to the first electrode layer 40.

In the semiconductor light emitting element 115 as well, the uniformity of the light emission can be increased by providing the first metal region 51, the second metal region 52, the third metal region 53, the fourth metal region 51a, the fifth metal region 52a, and the sixth metal region 53a recited above in the second electrode layer 50.

### Second Embodiment

FIG. 12A and FIG. 12B are schematic cross-sectional views illustrating a semiconductor light emitting element according to a second embodiment.

As shown in FIG. 12A, the semiconductor light emitting element 120 according to the embodiment includes the first semiconductor layer 10, the second semiconductor layer 20, the third semiconductor layer 30, the first electrode layer 40, and the second electrode layer 50.

The first semiconductor layer 10 has the first conductivity type (e.g., the n-type). The second semiconductor layer 20 has the second conductivity type (e.g., the p-type). The second semiconductor layer 20 includes the first semiconductor region 20a and the second semiconductor region 20b. The third semiconductor layer 30 is provided between the first semiconductor layer 10 and the second semiconductor layer 20. The stacked body 15 that includes the first semiconductor layer 10, the second semiconductor layer 20, and the third semiconductor layer 30 is provided in the example as well.

The first electrode layer 40 is electrically connected to the first semiconductor layer 10. The second electrode layer 50 is electrically connected to the second semiconductor layer 20. The second semiconductor layer 20 and the third semiconductor layer 30 are disposed between the second electrode layer 50 and the first semiconductor layer 10.

The second electrode layer 50 includes the first metal region 51, the second metal region 52, and an intermediate metal film 54. The first metal region 51 includes silver and contacts the first semiconductor region 20a. The first semiconductor region 20a is disposed between the first metal region 51 and the third semiconductor layer 30. The second metal region 52 includes silver and contacts the second semiconductor region 20b. The second semiconductor region 20b is disposed between the second metal region 52 and the third semiconductor layer 30.

The intermediate metal film 54 includes at least one of nickel, aluminum, or titanium. The first metal region 51 is disposed between the first semiconductor region 20a and at least a portion of the intermediate metal film 54.

The distance between the first metal region 51 and the first electrode layer 40 is shorter than the distance between the second metal region 52 and the first electrode layer 40. The first metal region 51 has the first average grain size. The second metal region 52 has the second average grain size that is smaller than the first average grain size. For example, the first average grain size is 0.205 μm or more; and the second average grain size is less than 0.205 μm. For example, the first average grain size is not less than 0.205 μm and not more than 0.30 μm. For example, the second average grain size is not less than 0.18 μm and not more than 0.195 μm.

For example, as described in regard to FIG. 6A, the contact resistance Rc is high and the average grain size is relatively large for annealing in an atmosphere including nitrogen. In such a case, the contact resistance Rc is reduced by further performing annealing in an atmosphere including oxygen after the annealing in the atmosphere including nitrogen.

The inventor of the application discovered that by providing the intermediate metal film 54 including at least one of nickel, aluminum, or titanium on the silver film that is annealed in the atmosphere including nitrogen, a high contact resistance Rc can be maintained even when subsequent annealing in the atmosphere including oxygen is performed. It is considered that this is because the penetration of the oxygen into the silver film is suppressed even when the annealing in the atmosphere including oxygen is performed because the silver film is covered with these metals.

In the embodiment, for example, a silver film that has a large average grain size (the silver film that is annealed in the atmosphere including nitrogen) is used as the first metal region 51. Thereby, a high contact resistance Rc is obtained for the first metal region 51. Then, the intermediate metal film 54 that includes at least one of nickel, aluminum, or titanium is provided on the silver film. A silver film that is annealed in the atmosphere including oxygen is used as the second metal region 52. The contact resistance Rc is low and the average grain size is small for the second metal region 52. A high contact resistance Rc of the first metal region 51 can be maintained even when the annealing in the atmosphere including oxygen is performed.

In the embodiment as well, the contact resistance of the first metal region 51 can be set to be higher than the contact resistance Rc of the second metal region 52. Thereby, the uniformity of the light emission can be increased.

For example, the contact resistance Rc between the first metal region 51 and the second semiconductor layer 20 (the first semiconductor region 20a) is not less than 5×10⁻³ Ωcm² and not more than 1×10⁻¹ Ωcm². For example, the contact resistance Rc between the second metal region 52 and the second semiconductor layer 20 (the second semiconductor region 20b) is not less than 1.5×10⁻⁴ Ωcm² and not more than 5.0×10⁻⁴ Ωcm².

In the semiconductor light emitting element 120, the second electrode layer 50 further includes the third metal region 53 that includes silver. At least a portion of the intermediate metal film 54 is disposed between the first metal region 51 and at least a portion of the third metal region 53. In other words, the third metal region 53 is further provided on at least a portion of the intermediate metal film 54. The penetration of the oxygen into the first metal region 51 is suppressed further by the third metal region 53. Thereby, the increase of the contact resistance Rc in the first metal region 51 is suppressed further.

For example, the third metal region 53 has the third average grain size. The third average grain size is smaller than the first average grain size. The third average grain size is, for example, substantially the same as the second average grain size (e.g., not less than 0.9 times and not more than 1.1 times).

In the semiconductor light emitting element 120 as well, the first electrode layer 40 is provided at the first surface 10a of the first semiconductor layer 10.

In another semiconductor light emitting element 121 according to the embodiment as shown in FIG. 12B, the first electrode layer 40 is provided at the second surface 10b of the first semiconductor layer 10. In the semiconductor light emitting element 121 as well, the contact resistance of the first metal region 51 can be set to be higher than the contact resistance Rc of the second metal region 52. Thereby, the uniformity of the light emission can be increased.

The configurations of the semiconductor light emitting elements 115 and 116 are applicable to the embodiment. In other words, the third semiconductor region 20aa and the fourth semiconductor region 20ba may be provided in the second semiconductor layer 20; and the fourth metal region 51a, the fifth metal region 52a, and the sixth metal region 53a may be provided in the second electrode layer 50. In such a case, the first electrode layer 40 may be provided at the first surface 10a or may be provided at the second surface 10b.

### Third Embodiment

The embodiment relates to a method for manufacturing a semiconductor light emitting element.

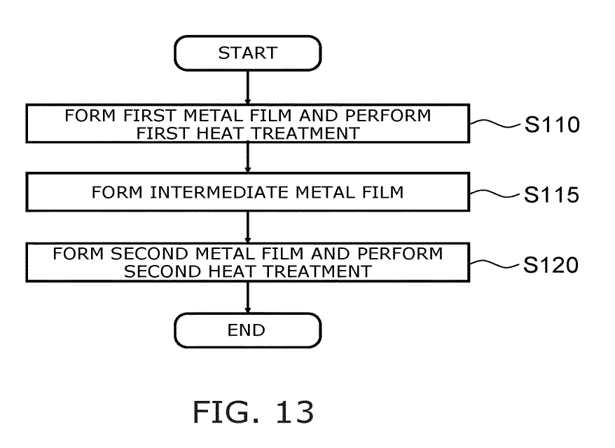

FIG. 13 is a flowchart illustrating the method for manufacturing the semiconductor light emitting element according to the third embodiment.

In the manufacturing method as shown in FIG. 13, the first metal film 51f that includes silver is formed on the first semiconductor region 20a of the second semiconductor layer 20 of the stacked body 15; and a first heat treatment of the first metal film 51f is performed in an atmosphere including nitrogen (step S110).

The stacked body 15 includes the first semiconductor layer 10, the second semiconductor layer 20, and the third semiconductor layer 30. The first semiconductor layer 10 includes the first semiconductor portion 10c and the second semiconductor portion 10d. The second semiconductor layer 20 is separated from the first semiconductor portion 10c in the first direction (the Z-axis direction) intersecting the direction (e.g., the X-axis direction) from the first semiconductor portion 10c toward the second semiconductor portion 10d. The third semiconductor layer 30 is provided between the first semiconductor portion 10c and the second semiconductor layer 20.

Then, the second metal film 52f that includes silver is formed on at least a portion of the first metal film 51f and on the second semiconductor region 20b of the second semiconductor layer 20; and a second heat treatment of the second metal film 52f is performed in an atmosphere including oxygen (step S120).

The first metal film 51f includes a portion that is covered with the second metal film 52f. A high contact resistance Rc is obtained at this portion by the annealing in the atmosphere including nitrogen. On the other hand, the second metal film 52f includes a portion that contacts the second semiconductor region 20b of the second semiconductor layer 20. A low contact resistance is obtained at this portion by the annealing in the atmosphere including oxygen. Thereby, the contact resistance of the first metal film 51f can be set to be higher than the contact resistance Rc of the second metal film 52f. Thereby, the uniformity of the light emission can be increased.

In the embodiment, an electrode (the first electrode layer 40) that is electrically connected to the second semiconductor portion 10d is formed in the second semiconductor portion 10d. The distance between the first metal film 51f and the second semiconductor portion 10d is shorter than the distance between the second metal film 52f and the second semiconductor portion 10d.

The processing temperature of the first heat treatment recited above is, for example, not less than 600° C. and not more than 850° C.; and the processing temperature of the second heat treatment is not less than 200° C. and not more than 400° C.

Or, the processing temperature of the first heat treatment is, for example, not less than 400° C. and not more than 500° C.; and the processing temperature of the second heat treatment is not less than 200° C. and not more than 400° C.

In the embodiment, the intermediate metal film 54 that includes at least one of nickel, aluminum, or titanium may be formed on the first metal film 51f (step S115) between step S110 and step S120. By forming the intermediate metal film 54, the decrease of the contact resistance Rc between the first metal film 51f and the second semiconductor layer 20 (the second semiconductor region 20b) can be suppressed when implementing the second heat treatment. In such a case, in step S120, the second metal film 52f that includes silver is formed on the second semiconductor region 20b of the second semiconductor layer 20; and the second heat treatment of the second metal film 52f may be performed in an atmosphere including oxygen. In other words, the second metal film 52f may not be provided on the first metal film 51f.

According to the embodiments, a semiconductor light emitting element and a method for manufacturing the semiconductor light emitting element in which the uniformity of the light emission can be increased are provided.

In the specification, “nitride semiconductor” includes all compositions of semiconductors of the chemical formula BₓIn_{y}Al_{z}Ga_{1-x-y-z}N (0≦x≦1, 0≦y≦1, 0≦z≦1, and x+y+z≦1) for which the composition ratios x, y, and z are changed within the ranges respectively. “Nitride semiconductor” further includes group V elements other than N (nitrogen) in the chemical formula recited above, various elements added to control various properties such as the conductivity type and the like, and various elements included unintentionally.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor light emitting devices such as stacked bodies, semiconductor layers, electrode layers, insulating layers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor light emitting devices and methods for manufacturing semiconductor light emitting devices practicable by an appropriate design modification by one skilled in the art based on the semiconductor light emitting devices, and the methods for manufacturing semiconductor light emitting devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting element, comprising:
a first semiconductor layer of a first conductivity type;
a second semiconductor layer of a second conductivity type, the second semiconductor layer including a first semiconductor region and a second semiconductor region;
a third semiconductor layer provided between the first semiconductor layer and the second semiconductor layer;
a first electrode layer electrically connected to the first semiconductor layer; and
a second electrode layer electrically connected to the second semiconductor layer,
the second semiconductor layer and the third semiconductor layer being disposed between the second electrode layer and the first semiconductor layer,
the second electrode layer including
a first metal region contacting the first semiconductor region and including silver,
a second metal region contacting the second semiconductor region and including silver, and
a third metal region contacting the first metal region and including silver,
the first metal region being disposed between the third metal region and the first semiconductor region,
a distance between the first metal region and the first electrode layer being shorter than a distance between the second metal region and the first electrode layer,
the first metal region having a first average grain size,
the second metal region having a second average grain size smaller than the first average grain size,
the third metal region having a third average grain size smaller than the first average grain size.

2. The element according to claim 1, wherein
the first average grain size is 0.205 micrometers or more,
the second average grain size is less than 0.205 micrometers, and
the third average grain size is less than 0.205 micrometers.

3. The element according to claim 2, wherein
the second average grain size is not less than 0.18 micrometers and not more than 0.195 micrometers, and
the third average grain size is not less than 0.18 micrometers and not more than 0.195 micrometers.

4. The element according to claim 3, wherein
the first average grain size is not less than 0.205 micrometers and not more than 0.30 micrometers.

5. The element according to claim 1, wherein
a first portion of the second electrode layer including the first metal region and the third metal region has a first thickness along a first direction from the first semiconductor layer toward the second semiconductor layer,
a second portion of the second electrode layer including the second metal region has a second thickness along the first direction,
the first thickness is thicker than the second thickness, and
an absolute value of a difference between the first thickness and the second thickness is not less than ½ of the second thickness and not more than twice the second thickness.

6. The element according to claim 1, wherein a surface area of the third metal region in a plane perpendicular to the first direction is not less than 0.8 times a surface area of the first metal region in the plane.

7. The element according to claim 1, wherein a contact resistance between the first metal region and the first semiconductor region is higher than a contact resistance between the second metal region and the second semiconductor region.

8. The element according to claim 1, wherein
the second semiconductor layer further includes a third semiconductor region and a fourth semiconductor region,
the first semiconductor region is disposed between the second semiconductor region and the fourth semiconductor region,
the third semiconductor region is disposed between the first semiconductor region and the fourth semiconductor region,
the first electrode layer is positioned between the first semiconductor region and the third semiconductor region in a direction from the second semiconductor region toward the fourth semiconductor region,
the second electrode layer includes:
a fourth metal region contacting the third semiconductor region and including silver;
a fifth metal region contacting the fourth semiconductor region and including silver; and
a sixth metal region contacting the fourth metal region and including silver,
the fourth metal region is disposed between the sixth metal region and the third semiconductor region,
the fourth metal region has a fourth average grain size,
the fifth metal region has a fifth average grain size smaller than the fourth average grain size, and
the sixth metal region has a sixth average grain size smaller than the fourth average grain size.

9. The element according to claim 8, wherein
the fourth average grain size is not less than 0.205 micrometers and not more than 0.30 micrometers,
the fifth average grain size is not less than 0.18 micrometers and not more than 0.195 micrometers, and
the sixth average grain size is not less than 0.18 micrometers and not more than 0.195 micrometers.

10. A semiconductor light emitting element, comprising:
a first semiconductor layer of a first conductivity type;
a second semiconductor layer of a second conductivity type, the second semiconductor layer including a first semiconductor region and a second semiconductor region;
a third semiconductor layer provided between the first semiconductor layer and the second semiconductor layer;
a first electrode layer electrically connected to the first semiconductor layer; and
a second electrode layer electrically connected to the second semiconductor layer,
the second semiconductor layer and the third semiconductor layer being disposed between the second electrode layer and the first semiconductor layer,
the second electrode layer including
a first metal region contacting the first semiconductor region and including silver,
a second metal region contacting the second semiconductor region and including silver, and
an intermediate metal film including at least one of nickel, aluminum, or titanium,
the first metal region being disposed between the first semiconductor region and at least a portion of the intermediate metal film,
a distance between the first metal region and the first electrode layer being shorter than a distance between the second metal region and the first electrode layer,
the first metal region having a first average grain size,
the second metal region having a second average grain size smaller than the first average grain size.

11. The element according to claim 10, wherein
the first average grain size is not less than 0.205 micrometers and not more than 0.30 micrometers, and
the second average grain size is not less than 0.18 micrometers and not more than 0.195 micrometers.

12. The element according to claim 10, wherein
the second electrode layer further includes a third metal region including silver, and
at least a portion of the intermediate metal film is disposed between the first metal region and at least a portion of the third metal region.

13. The element according to claim 12, wherein the third metal region has a third average grain size smaller than the first average grain size.

14. The element according to claim 1, wherein
the first semiconductor layer includes:
a first semiconductor portion; and
a second semiconductor portion arranged with the first semiconductor portion in a second direction intersecting a first direction from the first semiconductor layer toward the second semiconductor layer,
the second semiconductor layer and the third semiconductor layer are disposed between the first semiconductor portion and the second electrode layer, and
the first metal layer is connected to the second semiconductor portion.

15. The element according to claim 1, wherein
the first semiconductor layer has a first surface on a side of the third semiconductor layer, and
the first electrode layer is provided on the first surface.

16. The element according to claim 1, wherein
the first semiconductor layer has a first surface and a second surface, the first surface being on a side of the third semiconductor layer, the second surface being on a side opposite to the first surface, and
the first electrode layer is provided on the second surface.

17. A method for manufacturing a semiconductor light emitting element, comprising:
forming a first metal film on a first semiconductor region of a second semiconductor layer of a stacked body and performing a first heat treatment of the first metal film in an atmosphere including nitrogen, the first metal film including silver, the stacked body including
a first semiconductor layer of a first conductivity type, the first semiconductor layer including a first semiconductor portion and a second semiconductor portion,
the second semiconductor layer of a second conductivity type, the second semiconductor layer being separated from the first semiconductor portion in a first direction intersecting a direction from the first semiconductor portion toward the second semiconductor portion, and
a third semiconductor layer provided between the first semiconductor portion and the second semiconductor layer; and
forming a second metal film on at least a portion of the first metal film and on a second semiconductor region of the second semiconductor layer and performing a second heat treatment of the second metal film in an atmosphere including oxygen, the second metal film including silver.

18. The method according to claim 17, wherein
an electrode is formed on the second semiconductor portion, the electrode being electrically connected to the second semiconductor portion, and
a distance between the first metal film and the second semiconductor portion is shorter than a distance between the second metal film and the second semiconductor portion.

19. The method according to claim 17, wherein
a processing temperature of the first heat treatment is not less than 600° C. and not more than 850° C., and
a processing temperature of the second heat treatment is not less than 200° C. and not more than 400° C.

20. The method according to claim 17, wherein
a processing temperature of the first heat treatment is not less than 400° C. and not more than 500° C., and
a processing temperature of the second heat treatment is not less than 200° C. and not more than 400° C.
